(19) United States
(12) Patent Application Publication
(10) Pub. No.: US 2026/0250562 A1
(43) Pub. Date: Aug. 27, 2026

(54) ADHESIVE COMPOSITION, ADHESIVE SHEET, AND IMAGE DISPLAY DEVICE

(71) Applicant: DONGWOO FINE-CHEM CO., LTD., Jeonbuk-do (KR)

(72) Inventors: JIN WOO LEE, Jeonbuk-do (KR); HYE RIM KWON, Jeonbuk-do (KR); KYOUNG MOON JUNG, Jeonbuk-do (KR)

(21) Appl. No.: 19/651,945

(22) Filed: Apr. 20, 2026

Related U.S. Application Data
(63) Continuation of application No. PCT/KR2024/015506, filed on Oct. 14, 2024.

(30) Foreign Application Priority Data
Oct. 18, 2023 (KR) 10-2023-0139167

(51) Int. Cl. C09J 133/10; H05K 5/03

(52) U.S. Cl. CPC C09J 133/10; H05K 5/03

(57) ABSTRACT

An adhesive composition includes a (meth)acrylate copolymer that includes a repeating unit derived from a (meth)acrylate monomer including an alkyl group having 8 to 12 carbon atoms, a repeating unit derived from a (meth)acrylate monomer including an alkyl group having 20 to 30 carbon atoms, and a repeating unit derived from a hydroxyl group-containing (meth)acrylate monomer. An adhesive sheet and an image display device having improved high and low temperature folding properties are provided using the adhesive composition.

### CROSS-REFERENCE TO RELATED APPLICATION AND CLAIM OF PRIORITY

The present application is a continuation application to International Application No. PCT/KR2024/015506 with an International Filing Date of Oct. 14, 2024, which claims the benefit of Korean Patent Application No. 10-2023-0139167 filed on Oct. 18, 2023 at the Korean Intellectual Property Office, the disclosures of which are incorporated by reference herein in their entirety.

### BACKGROUND

### 1. Field

The present invention relates to an adhesive composition, an adhesive sheet, and an image display device.

### 2. Description of the Related Art

For example, an adhesive or an adhesive sheet may be used to adhere a display panel of an image display device such as a liquid crystal display (LCD) device or an organic light-emitting diode (OLED) device to various optical structures or circuit structures. Enhanced transparency for preventing degradation of optical properties of the image display device and enhanced adhesive strength are needed in the adhesive.

Recently, a flexible display or a foldable display capable of folding or bending is being actively developed, and thus a structure combined with the flexible display are also being designed to have appropriate elasticity and flexibility. Thus, properties for preventing detachment or delamination of a structure when being bent or folded are required in an adhesive or an adhesive sheet employed for combining the structure.

Further, a display having improved reliability under harsh conditions of high temperature and humidity, or external physical impact is being actively developed, and thus a structure combined with the display also needs to be formed to prevent detachment or delamination under the harsh conditions and external impact.

For example, Korean Published Patent Application No. 2010-0039274 discloses an adhesive for a polarizing plate applied to an image display device. However, flexibility and durability required for the flexible display may not be sufficiently achieved from a conventionally known adhesive.

### SUMMARY

According to an aspect of the present invention, there is provided an adhesive composition having improved mechanical properties.

According to an aspect of the present invention, there is provided an adhesive sheet having improved mechanical properties.

According to an aspect of the present invention, there is provided an image display device including the adhesive sheet.
(1) An adhesive composition, including a (meth)acrylate copolymer that includes: a repeating unit derived from a (meth)acrylate monomer including an alkyl group having 8 to 12 carbon atoms; a repeating unit derived from a (meth)acrylate monomer including an alkyl group having 20 to 30 carbon atoms; and a repeating unit derived from a hydroxyl group-containing (meth)acrylate monomer, wherein the (meth)acrylate copolymer satisfies Formula 1 below:

$$0.3 \leq B / A \leq 4 \qquad [ Formula 1 ]$$

wherein, in Formula 1, A is a content (wt %) of the repeating unit derived from the hydroxyl group-containing (meth)acrylate monomer based on a total weight of the (meth)acrylate copolymer, and B is a content (wt %) of the repeating unit derived from the (meth)acrylate monomer including an alkyl group having 20 to 30 carbon atoms based on the total weight of the (meth)acrylate copolymer.
(2) The adhesive composition of the above (1), wherein the (meth)acrylate copolymer satisfies Formula 2 below:

$$0.5 \leq B / A \leq 1.2 . \qquad [ Formula 2 ]$$

(3) The adhesive composition of the above (1), wherein A in Formula 1 is in a range from 10 to 60.
(4) The adhesive composition of the above (1), wherein B in Formula 1 is in a range from 10 to 45.
(5) The adhesive composition of the above (1), wherein the (meth)acrylate monomer including an alkyl group having 20 to 30 carbon atoms includes a branched-chain alkyl group having 20 to 30 carbon atoms.
(6) The adhesive composition of the above (1), wherein the content of the repeating unit derived from the (meth)acrylate monomer including an alkyl group having 8 to 12 carbon atoms is in a range from 10 wt % to 80 wt % based on the total weight of the (meth)acrylate copolymer.
(7) The adhesive composition of the above (1), wherein the (meth)acrylate copolymer further includes a repeating unit derived from a carboxyl group-containing (meth)acrylate monomer.
(8) The adhesive composition of the above (7), wherein the content of the repeating unit derived from the carboxyl group-containing (meth)acrylate monomer is greater than 0, and less than or equal to 5 wt % based on the total weight of the (meth)acrylate copolymer.
(9) The adhesive composition of the above (7), wherein the (meth)acrylate copolymer satisfies Formula 3:

$$0 < C / A \leq 0.1 \qquad [ Formula 3 ]$$

wherein, in Formula 3, A is the content (wt %) of the repeating unit derived from the hydroxyl group-containing (meth)acrylate monomer based on the total weight of the (meth)acrylate copolymer, and C is a content (wt %) of the repeating unit derived from the carboxyl group-containing (meth)acrylate monomer based on the total weight of the (meth)acrylate copolymer.
(10) The adhesive composition of the above (1), further including a crosslinking agent, wherein a content of the crosslinking agent is greater than 0, and less than or equal to 3 parts by weight based on 100 parts by weight of the (meth)acrylate copolymer.
(11) An adhesive sheet including an adhesive layer formed from the above-described adhesive composition.
(12) An image display device, including: a display panel; and the adhesive sheet disposed on the display panel
(13) An adhesive sheet including an adhesive layer that includes a (meth)acrylate copolymer, wherein an adhesive force of the adhesive layer at 25° C. is 16 N/25 mm or more, and a storage modulus of the adhesive layer at −20° C. is in a range from 50 kPa to 120 kPa, wherein the adhesive force is measured by laminating the adhesive layer to a glass substrate, maintaining for 24 hours under conditions of 25° C. and 50% RH, and then peeling the adhesive layer at a peeling speed of 300 mm/min and a peeling angle of 180°.
(14) The adhesive sheet of the above (13), wherein the (meth)acrylate copolymer includes: a repeating unit derived from a (meth)acrylate monomer including an alkyl group having 8 to 12 carbon atoms; a repeating unit derived from a (meth)acrylate monomer including an alkyl group having 20 to 30 carbon atoms; and a repeating unit derived from a hydroxyl group-containing (meth)acrylate monomer.
(15) An adhesive sheet including an adhesive layer that includes a (meth)acrylate-based copolymer, wherein a ratio of an adhesive force at 65° C. to an adhesive force at 25° C. of the adhesive layer is greater than 0.5, and less than or equal to 1.5, wherein the adhesive force at 25° C. is measured by laminating the adhesive layer to a glass substrate, maintaining under conditions of 25° C. and 50% RH for 24 hours, and then peeling the adhesive layer at a peeling speed of 300 mm/min and a peeling angle of 180°, and the adhesive force at 65° C. is measured by laminating the adhesive layer to a glass substrate, maintaining under conditions of 65° C. for 3 hours, and then peeling the adhesive layer at a peeling speed of 300 mm/min and a peeling angle of 180°.
(16) The adhesive sheet according to the above (15), wherein the (meth)acrylate copolymer includes: a repeating unit derived from a (meth)acrylate monomer including an alkyl group having 8 to 12 carbon atoms; a repeating unit derived from a (meth)acrylate monomer including an alkyl group having 20 to 30 carbon atoms; and a repeating unit derived from a hydroxyl group-containing (meth)acrylate monomer.

An adhesive composition according to example embodiments of the present invention includes a (meth)acrylate copolymer that includes a repeating unit derived from a (meth)acrylate monomer including an alkyl group having 8 to 12 carbon atoms; a repeating unit derived from a (meth)acrylate monomer including an alkyl group having 20 to 30 carbon atoms; and a repeating unit derived from a hydroxyl group-containing (meth)acrylate monomer. Accordingly, an adhesive layer having improved flexibility and a low low-temperature storage modulus may be implemented.

In some embodiments, the (meth)acrylate copolymer may include a repeating unit derived from a hydroxyl group-containing (meth)acrylate monomer and a repeating unit derived from a (meth)acrylate monomer including an alkyl group having 20 to 30 carbon atoms to satisfy a predetermined Formula 1. Accordingly, an adhesive sheet having improved folding performance under extreme conditions (e.g., cryogenic, high-temperature, high-humidity, etc., conditions) may be implemented.

An adhesive sheet according to example embodiments of the present invention may be formed from the adhesive composition, and may satisfy a predetermined room temperature (e.g., 25° C.) adhesive forces, a range of a ratio of room temperature and high temperature adhesive strengths, and/or a low-temperature elastic modulus range.

Accordingly, even when being repeatedly deformed in a cryogenic or high/high humidity environment, delamination or lifting between the adhesive sheet and an adhesive member may not occur, and folding performance of the adhesive sheet may be improved to be suitable for an application to a foldable display.

### DETAILED DESCRIPTION OF THE EMBODIMENTS

According to example embodiments, an adhesive composition including a (meth)acrylate copolymer that includes a repeating unit derived from a (meth)acrylate monomer including an alkyl group having 8 to 12 carbon atoms; a repeating unit derived from a (meth)acrylate monomer including an alkyl group having 20 to 30 carbon atoms; and a repeating unit derived from a hydroxyl group-containing (meth)acrylate monomer in a content ratio satisfying a predetermined formula. According to example embodiments, an adhesive sheet including the (meth)acrylate copolymer having high room-temperature adhesive force and a low storage modulus at low temperature is provided.

Hereinafter, the present disclosure will be described in detail with reference to example embodiments. However, those skilled in the art will appreciate that such embodiments are provided to further understand the spirit of the present invention and do not limit subject matters to be protected as disclosed in the detailed description and appended claims.

The term “(meth)acrylate” herein is used to encompass both a methacrylate and an acrylate.

The adhesive composition according to example embodiments includes a (meth)acrylate copolymer. The (meth)acrylate copolymer may be a copolymer of a monomer mixture including one or more type of a (meth)acrylate monomer.

In example embodiments, the (meth)acrylate copolymer may include a repeating unit derived from a (meth)acrylate monomer including an alkyl group having 8 to 12 carbon atoms. In some embodiments, the (meth)acrylate copolymer may include a repeating unit derived from a (meth)acrylate monomer including an alkyl group having 8 to 10 carbon atoms.

The (meth)acrylate monomer including an alkyl group having 8 to 12 carbon atoms may include a linear, branched or cyclic alkyl group having 8 to 12 carbon atoms.

Examples of the (meth)acrylate monomers including an alkyl group having 8 to 12 carbon atoms include 2-ethylhexyl(meth)acrylate, isooctyl(meth)acrylate, n-octyl(meth)acrylate, n-decyl(meth)acrylate, isodecyl(meth)acrylate, n-undecyl(meth)acrylate, isoundecyl(meth)acrylate, n-dodecyl(meth)acrylate, isododecyl(meth)acrylate, etc. These may be used alone or in a combination of two or more therefrom.

In example embodiments, a content of the repeating unit derived from the (meth)acrylate monomer including an alkyl group having 8 to 12 carbon atoms based on a total weight of the (meth)acrylate copolymer may be in a range from 10 wt % to 80 wt %. In some embodiments, a content of the repeating unit derived from the (meth)acrylate monomer including an alkyl group having 8 to 12 carbon atoms based on the total weight of the (meth)acrylate copolymer may be in a range from 15 wt % to 75 wt %, from 20 wt % to 75 wt %, or from 20 wt % to 70 wt %.

The “content of a repeating unit derived from a monomer” herein may be substantially the same as a content of the monomer based on a total weight of the monomer mixture.

In the above content range, high-temperature folding properties of the adhesive sheet formed from the adhesive composition may be improved.

In example embodiments, the (meth)acrylate copolymer may include a repeating unit derived from a (meth)acrylate monomer including an alkyl group having 20 to 30 carbon atoms. The (meth)acrylate copolymer may include the repeating unit derived from the monomer including a long-chain alkyl group, a hardness of the adhesive sheet may not be excessively increased even at low temperature, and may have a low storage modulus to have enhanced flexibility.

In some embodiments, the (meth)acrylate copolymer may include a repeating unit derived from a (meth)acrylate monomer including an alkyl group having 21 to 30 carbon atoms. In an embodiment, the (meth)acrylate copolymer may include a repeating unit derived from a (meth)acrylate monomer including an alkyl group having 24 to 30 carbon atoms. If the above range, the high-temperature folding properties of the adhesive sheet may be improved.

If the (meth)acrylate copolymer includes a repeating unit derived from a (meth)acrylate monomer including an alkyl group having carbon atoms less than 20 instead of the repeating unit derived from the (meth)acrylate monomer including an alkyl group having 20 to 30 carbon atoms, the low-temperature storage modulus of the adhesive sheet may be reduced. Accordingly, flexibility of the adhesive sheet may be reduced, and detachment from the adhesive member may occur during repeated folding.

In example embodiments, the (meth)acrylate monomer including an alkyl group having 20 to 30 carbon atoms may include a branched-chain alkyl group having 20 to 30 carbon atoms. The branched-chain alkyl group may include a structure in which at least one carbon is bonded to three or more alkyl chains, so that a volume of the molecule may be increased. Accordingly, excessive increase of a density and a hardness of the adhesive sheet may be prevented, and flexibility of the adhesive sheet may be improved and the folding properties may be achieved.

In example embodiments, the (meth)acrylate monomer including an alkyl group having 20 to 30 carbon atoms may include a compound represented by Chemical Formula 1 below.

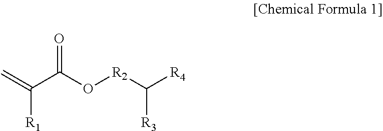

In Chemical Formula 1, R₁ may be hydrogen or a methyl group. If R₁ is hydrogen, the compound represented by Chemical Formula 1 may be an acrylate compound. If R₁ is a methyl group, the compound represented by Chemical Formula 1 may be a methacrylate compound.

In Chemical Formula 1, R₂ may be a direct bond or a linear alkylene group having 1 to 27 carbon atoms, R₃ and R₄ may be linear alkyl groups having 1 to 27 carbon atoms, and a sum of the carbon atoms included in R₂ to R₄ may be 19 to 29. In some embodiments, R₂ may be a direct bond or a linear alkylene group having 1 to 3 carbon atoms, R₃ and R₄ may be linear alkyl groups having 5 to 20 carbon atoms, and the sum of the carbon atoms included in R₂ to R₄ may be 19 to 29.

In some embodiments, in Chemical Formula 1, R₂ is a methylene group, and a sum of the carbon atoms included in R₃ and R₄ may be 18 to 28. In this case, the volume of the (meth)acrylate copolymer may be increased to reduce the density of the adhesive sheet. Accordingly, flexibility of the adhesive sheet may be increased, and the folding properties may be improved.

In example embodiments, difference of the number of carbon atoms included in R₃ and R₄ in Chemical Formula 1 may be 2 to 20. In some embodiments, the difference of the number of carbon atoms included in R₃ and R₄ in Chemical Formula 1 may be 2 to 10, 3 to 9, or 4 to 8. In the above ranges, a difference in length between R₃ and R₄ may be properly adjusted to further increase the volume of the (meth)acrylate copolymer.

Examples of the (meth)acrylate monomer including an alkyl group having 20 to 30 carbon atoms include 2-ethyloctadecyl(meth)acrylate, 2-butylhexadecyl(meth)acrylate, 2-hexyltetradecyl(meth)acrylate, 2-octyldodecyl(meth)acrylate, 1-octyldodecyl(meth)acrylate, 2-octylhexadecyl 71 (meth)acrylate, 2-decyltetradecyl(meth)acrylate, 1-decyltetradecyl(meth)acrylate, 2-undecyltridecyl(meth)acrylate, 2-dodecylhexadecyl(meth)acrylate, 1-dodecylhexadecyl(meth)acrylate, etc. These may be used alone or in a combination of two or more therefrom.

In example embodiments, the content of the repeating unit derived from the (meth)acrylate monomer including an alkyl group having 20 to 30 carbon atoms based on the total weight of the (meth)acrylate copolymer may be in a range from 10 wt % to 45 wt %. In some embodiments, the content of the repeating unit derived from the (meth)acrylate monomer including an alkyl group having 20 to 30 carbon atoms based on the total weight of the (meth)acrylate copolymer may be 20 wt % or more or 25 wt % or more, and 60 wt % or less or 50 wt % or less.

In the above content range, low-temperature folding properties of the adhesive sheet formed from the adhesive composition may be improved.

In example embodiments, the (meth)acrylate copolymer may include a repeating unit derived from a hydroxyl group-containing (meth)acrylate monomer. The hydroxyl group may be a binding site where copolymer chains may be combined with each other.

When the (meth)acrylate copolymers are bonded by the hydroxyl groups, an adhesive layer may be formed by a crosslinking of the (meth)acrylate copolymers included in the adhesive composition.

Examples of the hydroxyl group-containing (meth)acrylate monomer include 2-hydroxyethyl(meth)acrylate, 3-hydroxypropyl(meth)acrylate, 4-hydroxybutyl(meth)acrylate, 5-hydroxypentyl(meth)acrylate, 6-hydroxyhexyl(meth)acrylate, 8-hydroxyoctyl(meth)acrylate, 10-hydroxydecyl(meth)acrylate, 12-hydroxylauryl(meth)acrylate, (4-hydroxymethylcyclohexyl)methylacrylate, N-methylol (meth)acrylamide, etc. These may be used alone or in a combination of two or more therefrom.

In example embodiments, a content of the repeating unit derived from the hydroxyl group-containing (meth)acrylate monomer based on the total weight of the (meth)acrylate copolymer may be in a range from 10 wt % to 60 wt %. In some embodiments, the content of the repeating unit derived from the hydroxyl group-containing (meth)acrylate monomer based on the total weight of the (meth)acrylate copolymer may be in a range from 15 wt % to 50 wt %, or from 15 wt % to 40 wt %.

In the above range, the number of crosslinking sites at which the (meth)acrylate copolymer may be crosslinked may be properly adjusted. Accordingly, flexibility of the adhesive sheet may be improved while achieving a crosslinking degree required to form an adhesive layer.

The (meth)acrylate copolymer may further include a repeating unit derived from a carboxyl group-containing (meth)acrylate monomer. The carboxyl group may act as an acidic group to regulate a pH of the monomer mixture, and may serve as a crosslinking site to connect chains of the (meth)acrylate copolymers together with the hydroxyl group.

Examples of the carboxyl group-containing (meth)acrylate monomer include (meth)acrylic acid, carboxyethyl(meth)acrylate, carboxypentyl(meth)acrylate, etc. In some embodiments, the carboxyl group-containing (meth)acrylate monomer may include (meth)acrylic acid or carboxyethyl (meth)acrylate.

In example embodiments, a content of the repeating unit derived from the carboxyl group-containing (meth)acrylate monomer based on the total weight of the (meth)acrylate copolymer may be greater than 0, and less than or equal to 5 wt %. In some embodiments, the content of the repeating unit derived from the carboxyl group-containing (meth)acrylate monomer based on the total weight of the (meth)acrylate copolymer may be in a range from 0.5 wt % to 3 wt %, or from 0.5 wt % to 2 wt %.

The (meth)acrylate copolymer may not include a repeating unit derived from the carboxyl group-containing (meth)acrylate monomer. For example, the monomer mixture may not include the carboxyl group-containing (meth)acrylate monomer when adjustment of an acidity of the monomer mixture may not be required, or the carboxyl group-containing (meth)acrylate monomer may not be added in consideration of compatibility with another additive.

The (meth)acrylate copolymer may further include a repeating unit derived from a monomer containing another functional group. The term “another functional group” may refer to a functional group that may be different from the hydroxyl group and the carboxyl group, and may possess reactivity to participate in the crosslinking of the (meth)acrylate copolymer chains.

For example, the monomer containing another functional group may include a monomer containing a phosphate group, a monomer containing a sulfonic acid group, a monomer containing a cyano group, a vinyl ester monomer, a styrene-based monomer, a monomer containing an acid anhydride group, a monomer containing an amide group, a monomer containing an amino group, a monomer containing an imide group, a monomer containing an epoxy group, a monomer containing an ether group, etc. These may be used alone or in a combination of two or more therefrom.

Examples of the monomer containing a phosphate group include 2-hydroxyethylacryloyl phosphate, etc.

Examples of the monomer containing a sulfonic acid group include styrenesulfonic acid, allylsulfonic acid, 2-(meth)acrylamido-2-methylpropane sulfonic acid, (meth)acrylamidopropane sulfonic acid, sulfopropyl(meth)acrylate, (meth)acryloyloxynaphthalene sulfonic acid, sodium vinyl sulfonate, etc.

Examples of the monomer containing a cyano group include (meth)acrylonitrile, etc.

Examples of the vinyl ester monomer include vinyl acetate, vinyl propionate, vinyl laurate, etc.

Examples of the styrene-based monomers include styrene, chlorostyrene, chloromethylstyrene, α-methylstyrene, other substituted styrenes, etc.

Examples of the monomer containing an acid anhydride group include maleic anhydride, itaconic anhydride, an acid anhydride thereof, etc.

Examples of the monomer containing an amino group include aminoethyl(meth)acrylate, N,N-dimethylaminoethyl(meth)acrylate, N,N-dimethylaminopropyl(meth)acrylate, (meth)acryloylmorpholine, etc.

Examples of the monomer containing an imide group include cyclohexylmaleimide, isopropylmaleimide, N-cyclohexylmaleimide, itaconimide, etc.

Examples of the monomer containing an epoxy group include glycidyl(meth)acrylate, methylglycidyl(meth)acrylate, allylglycidyl ether, etc. Examples of the monomer containing an ether group include methoxyethyl

(meth)acrylate, ethoxymethyl(meth)acrylate, ethoxyethyl(meth)acrylate, propoxyethyl(meth)acrylate, butoxyethyl(meth)acrylate, methoxypropyl(meth)acrylate, methoxybutyl(meth)acrylate, ethoxy-diethylene glycol (meth)acrylate, methoxy-triethylene glycol (meth)acrylate, 2-ethylhexyl-diglycol (meth)acrylate, methoxy-polyethylene glycol (meth)acrylate, methoxydipropylene glycol (meth)acrylate, etc.

The aforementioned examples of the monomers may be used alone or in a combination of two or more therefrom.

A content of the repeating unit derived from the monomer containing another functional group may be 5 wt % or less, or 3 wt % or less based on the total weight of the (meth)acrylate copolymer.

In example embodiments, the (meth)acrylate copolymer satisfies Formula 1 below. In some embodiments, the (meth)acrylate copolymer may satisfy Formula 2 below.

$$0.3 \leq B / A \leq 4 \qquad [ Formula 1 ]$$

$$0.5 \leq B / A \leq 1.2 \qquad [ Formula 2 ]$$

In Equations 1 and 2, A is a content (wt %) of the repeating unit derived from the hydroxyl group-containing (meth)acrylate monomer based on the total weight of the (meth)acrylate copolymer. B is a content (wt %) of the repeating unit derived from the (meth)acrylate monomer including an alkyl group having 20 to 30 carbon atoms based on the total weight of the (meth)acrylate copolymer.

The (meth)acrylate copolymer satisfies Formula 1 (and Formula 2), so that the (meth)acrylate copolymer may contain the sufficiently large number of crosslinking sites to form an adhesive layer. Additionally, the (meth)acrylate copolymer may contain bulky long-chain alkyl groups, so that flexibility and foldability in harsh environments (e.g., cryogenic or high/high humidity environments) of the adhesive sheet may be enhanced.

If B/A in Formula 1 exceeds 4, the content of the repeating unit derived from the (meth)acrylate monomer including an alkyl group having 20 to 30 carbon atoms may be excessively increased. In this case, high-temperature folding properties of the adhesive sheet such as high-temperature and high-humidity folding properties may be degraded.

In some embodiments, B/A in Formula 1 may be 0.01 or more, 0.2 or more, 0.3 or more, or 0.4 or more, and B/A in Formula 1 may be 1.5 or less, 1.4 or less, 1.3 or less, 1.2 or less, or 1.1 or less.

In example embodiments, the (meth)acrylate copolymer may satisfy Formula 3.

$$0 < C / A \leq 0.1 \qquad [ Formula 3 ]$$

In Formula 3, A is a content (wt %) of the repeating unit derived from the hydroxyl group-containing (meth)acrylate monomer based on the total weight of the (meth)acrylate copolymer. C is a content (wt %) of the repeating unit derived from the carboxyl group-containing (meth)acrylate monomer based on the total weight of the (meth)acrylate copolymer.

The (meth)acrylate copolymer may satisfy Formula 3, so that the (meth)acrylate copolymer may contain the hydroxyl group and the carboxyl group in an appropriate proportion, and the hydroxyl group may react with a crosslinking agent as a main crosslinking site to form crosslinking bonds, while the carboxyl group may form an additional crosslink as an auxiliary crosslinking site.

In example embodiments, the (meth)acrylate copolymer may satisfy Formula 4.

$$0.01 \leq B / D \leq 20 \qquad [ Formula 4 ]$$

In Formula 4 above, D is a content (wt %) of the repeating unit derived from the (meth)acrylate monomer including an alkyl group having 8 to 12 carbon atoms based on the total weight of the (meth)acrylate copolymer. B is a content (wt %) of the repeating unit derived from the (meth)acrylate monomer including a branched-chain alkyl group having 20 to 30 carbon atoms based on the total weight of the (meth)acrylate copolymer.

In the above range, the low-temperature storage modulus of the (meth)acrylate copolymer may become low, so that the low-temperature folding characteristics may be improved, and high-temperature adhesion and high-temperature folding properties may also be improved.

In some embodiments, B/D of Formula 4 may be 0.01 or more, or 0.2 or more, and may be 20 or less, 10 or less, 1 or less, 0.4 or less, or 0.35 or less.

In example embodiments, a weight-average molecular weight of the (meth)acrylate copolymer may be in a range from about 500,000 to 3 million. In some embodiments, the weight-average molecular weight of the (meth)acrylate copolymer may be in a range from about 1 million to 2 million.

In example embodiments, the adhesive composition may include the (meth)acrylate copolymer in an amount from 50 wt % to 99.99 wt %. In some embodiments, the adhesive composition may include the (meth)acrylate copolymer in an amount from 60 wt % to 99.99 wt %, from 70 wt % to 99 wt %, from 80 wt % to 98 wt %, or from 90 wt % to 95 wt %.

In example embodiments, the adhesive composition may further include a crosslinking agent. When the adhesive composition contains the crosslinking agent, the crosslinking agent may contain a functional group that may react with a cross-linkable functional group derived from a cross-linkable group-containing monomer of the (meth)acrylate copolymer, so that cohesiveness and adhesion of the adhesive composition may be improved while maintaining shape and durability of the adhesive sheet.

Examples of the crosslinking agent include an isocyanate-based crosslinking agent, an epoxy-based crosslinking agent, an oxazoline-based crosslinking agent, an aziridine-based crosslinking agent, a metal chelate-based compound, etc. These may be used alone or in a combination of two or more therefrom.

Examples of the isocyanate-based crosslinking agent include a polyfunctional isocyanate compound such as toluene diisocyanate, xylene diisocyanate, diphenylmethane diisocyanate, hexamethylene diisocyanate, isoborone diisocyanate, tetramethylxylene diisocyanate, naphthalene diisocyanate, etc., or a compound obtained by reacting the above-mentioned polyfunctional isocyanate compound with a polyol compound such as trimethylolpropane. These may be used alone or in a combination of two or more therefrom.

Examples of the epoxy-based crosslinking agent include ethylene glycol diglycidyl ether, triglycidyl ether, trimethylolpropane triglycidyl ether, N,N,N′,N′-tetraglycidyl ethylenediamine, glycerin diglycidyl ether, etc. These may be used alone or in a combination of two or more therefrom.

Examples of the oxazoline-based crosslinking agent include a copolymer polymerized using at least one monomer containing an oxazoline group such as 2-vinyl-2-oxazoline, 2-vinyl-4-methyl-2-oxazoline, 2-vinyl-5-methyl-2-oxazoline, 2-isopropenyl-2-oxazoline, 2-isopropenyl-4-methyl-2-oxazoline, 2-isopropenyl-5-ethyl-2-oxazoline, etc. These may be used alone or in a combination of two or more therefrom.

Examples of the aziridine-based crosslinking agent include N,N′-toluene-2,4-bis(1-aziridinecarboxamide), N,N′-diphenylmethane-4,4′-bis(1-aziridinecarboxamide), triethylene melamine, bis-isophthaloyl-1-(2-methylaziridine), tri-1-aziridinylphosphine oxide, etc. These may be used alone or in a combination of two or more therefrom.

Examples of the metal chelate-based crosslinking agent include a compound in which a polyvalent metal such as aluminum, iron, zinc, tin, titanium, antimony, magnesium, and/or vanadium are coordinated with acetylacetone, ethyl acetoacetate, etc. These may be used alone or in a combination of two or more therefrom.

In example embodiments, a content range of the crosslinking agent may be greater than 0, and less than or equal to 3 parts by weight based on 100 parts by weight of the (meth)acrylate copolymer. In some embodiments, the content range of the crosslinking agent may be in a range from 0.1 parts by weight to 1 part by weight based on 100 parts by weight of the (meth)acrylate copolymer. In the above range, the (meth)acrylate copolymer may be crosslinked to form an adhesive layer without excessive curing, so that flexibility of the adhesive sheet may be achieved.

In example embodiments, the adhesive composition may further include a plasticizer, an antioxidant, a corrosion inhibitor, a leveling agent, a surface lubricant, an antifoaming agent, a filler, a light stabilizer, a reaction initiator, a solvent, etc. These may be used alone or in a combination of two or more therefrom, and the content thereof may be controlled within a range that does not degrade properties of the adhesive composition.

In example embodiments, examples of the plasticizer include triphenyl phosphate (TPP), tricresyl phosphate (TCP), cresyl diphenyl phosphate, octyl diphenyl phosphate, biphenyl diphenyl phosphate (BDP), trioctyl phosphate, tributyl phosphate, dimethyl phthalate (DMP), diethyl phthalate (DEP), dibutyl phthalate (DBP), dioctyl phthalate (DOP), diphenyl phthalate (DPP), diethylhexyl phthalate (DEHP), triethyl O-acetyl citrate (OACTE), tributyl O-acetyl citrate (OACTB), acetyl triethyl citrate, acetyl tributyl citrate, butyl oleate, methyl acetylicinoleate, dibutyl sebacate, triacetin, tributylin, butylphthalyl glycolate, ethylphthalyl ethyl glycolate, methylphthalyl ethyl glycolate, butylphthalylbutyl glycolate, etc. These may be used alone or in a combination of two or more therefrom.

In example embodiments, a content range of the plasticizer may be greater than 0, and less than or equal to 15 parts by weight based on 100 parts by weight of the (meth)acrylate copolymer. In some embodiments, the content range of the plasticizer may be greater than 0, and less than or equal to 10 parts by weight based on 100 parts by weight of the (meth)acrylate copolymer. In the above content range, the high-temperature folding properties of the adhesive sheet may be improved.

According to example embodiments, an adhesive sheet including an adhesive layer formed from the adhesive composition may be provided.

The adhesive layer may be prepared by applying the adhesive composition to a thickness of about 20 μm to 150 μm, and drying at about 90° C. to 150° C. for 1 to 15 minutes.

In some embodiments, the adhesive sheet may include the adhesive layer, a substrate film, and a protective film. The adhesive layer may be formed on the substrate film, and the protective film may be further formed on a top surface of the adhesive layer. The substrate film and/or the protective film may be a release film that may be removed before or after being attached to an attachment object.

The substrate film and the protective film may be resin films including, e.g., an acrylic resin, a cellulose-based resin, a polyolefin-based resin, a polyester-based resin, a polyimide-based resin, etc. The substrate film and the protective film may be surface-treated, e.g., with a silicone-based release agent.

In example embodiments, the adhesive composition may be applied to the substrate film, and dried to form an adhesive layer. An additional curing may be performed by applying a thermal energy or a light energy to the adhesive layer to induce further crosslinking.

Thereafter, the protective film may be attached to the adhesive layer.

In example embodiments, the adhesive sheet including an adhesive layer that has an adhesive force of 16 N/25 mm or more at 25° C. and includes the (meth)acrylate copolymer. In some embodiments, the adhesive force of the adhesive layer at 25° C. may be 18 N/25 mm or more, 20 N/25 mm or more, or 22 N/25 mm or more.

The above-described (meth)acrylate copolymer may be used.

The adhesive force at 25° C. may be measured by laminating the adhesive layer on a glass substrate, maintaining under conditions of 25° C. and 50% RH for 24 hours, and then peeling the adhesive layer at a peeling speed of 300 mm/min and a peeling angle of 180°.

The above-described adhesive sheet may have high adhesion to glass to be firmly attached to a glass substrate such as a cover window of an image display device including the adhesive sheet, and durability of the device may be improved.

In example embodiments, an adhesive sheet including an adhesive layer that includes the (meth)acrylate copolymer is provided. A ratio of an adhesive force at 65° C. to an adhesive force at 25° C. of the adhesive layer is greater than 0.5, and less than or equal to 1.5. In some embodiments, the ratio of the adhesive force at 65° C. to the adhesive force at 25° C. of the adhesive layer may be 0.6 or greater or 0.7 or greater, and may be 1.3 or less, 1.2 or less, or 1.1 or less.

The above-described (meth)acrylate copolymer may be used.

The adhesive force at 25° C. may be measured by the same method as that described above. The adhesive force at 65° C. may be measured by laminating the adhesive layer on a glass substrate, maintaining at 65° C. for 3 hours, and then peeling the adhesive layer at a peeling speed of 300 mm/min and a peeling angle of 180°.

The adhesive sheet may have high adhesive force to glass at room temperature and also at high temperature, so that detachment from the glass substrate may not occur and the high-temperature durability of the device may be improved even when operating the image display device including the adhesive sheet in a high-temperature environment.

In example embodiments, an adhesive sheet including an adhesive layer that includes the (meth)acrylate copolymer is provided. The adhesive layer may have a storage modulus at −20° C. in a range from 50 kPa to 120 kPa. In some embodiments, the storage modulus of the adhesive layer at −20° C. may be 50 kPa or more, 55 kPa or more, or 60 kPa or more, and may be 110 kPa or less, 100 kPa or less, or 90 kPa or less.

The above-described (meth)acrylate-based copolymer may be used.

The adhesive sheet may have a low storage modulus at low temperature to have high flexibility even in low-temperature environment. Accordingly, the low-temperature folding properties of the adhesive sheet may be improved.

The adhesive layer included in the adhesive sheet according to example embodiments may be formed from the adhesive composition as described above.

The image display device according to example embodiments may include a display panel and the adhesive sheet disposed on the display panel.

For example, the protective film may be removed/detached from the adhesive layer, and an exposed surface of the adhesive layer may be attached to the display panel.

The display panel may be a liquid crystal display (LCD) panel, an organic light-emitting display (OLED) panel, or a quantum dot light-emitting display (QLED) panel. In an embodiment, the display panel may include a flexible resin substrate such as polyimide, and flexible or folding properties of the image display device may be improved.

In some embodiments, the image display device may be a flexible display or a foldable display.

The image display device may further include other components/structures known in the related art. For example, a retardation film, a hard coating film, a protective film, a window film, a touch panel, a polarizer, etc., may be further included.

In some embodiments, the substrate film may be removed/detached from the adhesive layer, and the components/structures may be attached to an exposed surface of the adhesive layer. Additionally, the components/structures may be attached to each other by the adhesive layer according to example embodiments.

Hereafter, embodiments of the present invention will be further described with reference to specific experimental examples. The examples and comparative examples included in the experimental examples are merely illustrative of the present invention and are not intended to limit the appended claims. It is obvious to those skilled in the art that various changes and modifications to examples are possible within the scope and spirit of the present invention, and it is also natural that such variations and modifications fall within the scope of the appended claims.

### Preparation Example 1

100 parts by weight of a monomer mixture (69 wt % 2-ethylhexyl acrylate (2-EHA), 15 wt % 2-octyldodecyl acrylate (C20AA), 15 wt % 4-hydroxybutyl acrylate (4-HBA), and 1 wt % acrylic acid (AA)) and 100 parts by weight of ethyl acetate (EAc) as a solvent were introduced into a 1 L reactor. Oxygen was removed by purging with a nitrogen gas for 1 hour, and a temperature was maintained at 80° C. After uniformly mixing the monomer mixture and the solvent, 0.07 parts by weight of azobisisobutyronitrile (AIBN) were introduced as a reaction initiator, and a reaction was carried out for 8 hours to prepare a copolymer (weight-average molecular weight: 1.4 million).

### Preparation Examples 2 to 19

(Meth)acrylate-based copolymers were prepared by the same method as that in Preparation Example 1, except that the composition of the monomer mixture was adjusted as shown in Table 1 below. Additionally, the weight-average molecular weight (Mw) (*10⁴) of the prepared copolymers are shown in Table 1 below.

TABLE 1

| | | | | | other | Mw |
|---|---|---|---|---|---|---|
| | (a) | (b) | (c) | (d) | component | (*10⁴) |
| Preparation | (a-1) 69 | (b-1) 15 | (c-1) 15 | (d-1) 1 | — | 140 |
| Example 1 | | | | | | |
| Preparation | (a-1) 30 | (b-2) 25 | (c-1) 30 | (d-2) 1 | — | 135 |
| Example 2 | (a-3) 14 | | | | | |
| Preparation | (a-1) 29.5 | (b-2) 20 | (c-1) 50 | (d-1) 0.5 | — | 131 |
| Example 3 | | | | | | |
| Preparation | (a-1) 29 | (b-3) 20 | (c-2) 30 | (d-2) 1 | — | 138 |
| Example 4 | (a-2) 20 | | | | | |
| Preparation | (a-1) 29 | (b-3) 20 | (c-1) 10 | (d-1) 1 | — | 152 |
| Example 5 | (a-2) 10 | | (c-3) 30 | | | |
| Preparation | (a-1) 20 | (b-2) 40 | (c-1) 30 | (d-1) 2 | — | 112 |
| Example 6 | | | (c-4) 8 | | | |
| Preparation | (a-2) 70 | (b-2) 15 | (c-2) 15 | — | — | 102 |
| Example 7 | | | | | | |
| Preparation | (a-2) 39 | (b-2) 40 | (c-2) 20 | (d-1) 1 | — | 126 |
| Example 8 | | | | | | |
| Preparation | (a-3) 39 | (b-3) 30 | (c-1) 30 | (d-2) 1 | — | 113 |
| Example 9 | | | | | | |
| Preparation | (a-1) 24 | (b-1) 60 | (c-1) 15 | (d-1) 1 | — | 133 |
| Example 10 | | | | | | |
| Preparation | (a-1) 19 | (b-1) 20 | (c-1) 60 | (d-1) 1 | — | 141 |
| Example 11 | | | | | | |
| Preparation | (a-2) 33 | (b-2) 36 | (c-2) 30 | (d-1) 1 | — | 125 |
| Example 12 | | | | | | |
| Preparation | — | — | (c-1) 10 | — | (C4) 90 | 134 |
| Example 13 | | | | | | |
| Preparation | — | — | (c-1) 5 | (d-1) 1 | (C4) 94 | 85 |
| Example 14 | | | | | | |
| Preparation | (a-1) 29.5 | (b-3) 20 | — | (d-1) 0.5 | (C4) 50 | 108 |
| Example 15 | | | | | | |
| Preparation | (a-1) 30 | — | (c-1) 10 | — | (C4) 60 | 115 |
| Example 16 | | | | | | |
| Preparation | (a-1) 39 | (b-1) 50 | (c-1) 10 | (d-1) 1 | — | 137 |
| Example 17 | | | | | | |
| Preparation | (a-1) 69 | — | (c-1) 15 | (d-1) 1 | (C18) 15 | 124 |
| Example 18 | | | | | | |
| Preparation | (a-1) 49 | (b-1) 10 | (c-1) 40 | (d-1) 1 | — | 130 |
| Example 19 | | | | | | |

(a): (meth)acrylate monomer including an alkyl group having 8 to 12 carbon atoms
(a-1): 2-ethylhexyl acrylate (Sigma-Aldrich)
(a-2): iso-octyl acrylate (Japan Catalytic)
(a-3): lauryl acrylate (Kyoeisha)
(b): (meth)acrylate monomer including an alkyl group having 20 to 30 carbon atoms
(b-1): 2-dodecylhexadecyl acrylate (Kukjeon Pharm)
(b-2): 2-decyltetradecyl acrylate (Kukjeon Pharm)
(b-3): 2-octyldodecyl acrylate (Kukjeon Pharm)
(c): hydroxyl group-containing (meth)acrylate monomer
(c-1): 4-hydroxybutyl acrylate (Sigma-Aldrich)
(c-2): 5-hydroxypentyl acrylate (Sigma Aldrich)
(c-3): 6-hydroxyhexyl acrylate (Kukjeon Pharm)
(c-4): 2-hydroxyethyl acrylate (Sigma Aldrich)
(d): carboxyl group-containing (meth)acrylate monomer
(d-1): acrylic acid (Sigma Aldrich)
(d-2): carboxyethyl acrylate (Sigma Aldrich)
C4: butyl acrylate (Sigma Aldrich)
C18: stearyl acrylate (Sigma Aldrich)

### Examples 1 to 14 and Comparative Examples 1 to 8

Adhesive compositions were prepared by controlling types of the copolymer and a crosslinking agent, and contents of the copolymer, the crosslinking agent and a plasticizer as shown in Tables 2 and 3 below. The contents of the crosslinking agent and plasticizer was stated as parts by weight based on 100 parts by weight of the copolymer.

The prepared adhesive composition was applied to a 50 μm release film coated with a silicone release agent to a thickness of 50 μm, dried at 110° C. for 5 minutes, and then laminated with the release film to form an adhesive sheet.

TABLE 2

| | | Examples | | | | | | | | | | | | | |
|---|---|---|---|---|---|---|---|---|---|---|---|---|---|---|---|
| | | 1 | 2 | 3 | 4 | 5 | 6 | 7 | 8 | 9 | 10 | 11 | 12 | 13 | 14 |
| copolymer | | 1 | 2 | 3 | 2 | 2 | 4 | 5 | 6 | 7 | 8 | 9 | 10 | 11 | 12 |
| (Preparation | | | | | | | | | | | | | | | |
| Example) | | | | | | | | | | | | | | | |
| cross- | A | 0.2 | 0.2 | 0.2 | | | 0.1 | 0.1 | 0.05 | 0.2 | 0.1 | 0.1 | | | |
| linking | B | | | | 0.3 | | | | | | | | | | |
| agent | C | | | | | 0.5 | 0.3 | 0.3 | 0.3 | | | | 0.3 | 0.3 | 0.3 |

| | | | | |
|---|---|---|---|---|
| plasticizer | 5 | 3 | 5 | 3 |

TABLE 3

| | | Comparative Examples | | | | | | | |
|---|---|---|---|---|---|---|---|---|---|
| | | 1 | 2 | 3 | 4 | 5 | 6 | 7 | 8 |
| copolymer | | 13 | 13 | 14 | 15 | 16 | 17 | 18 | 19 |
| (Preparation | | | | | | | | | |
| Example) | | | | | | | | | |
| cross- | A | | 0.1 | | 0.2 | 0.2 | | | |
| linking | B | 0.3 | | 0.3 | | | 0.3 | 0.3 | 0.3 |
| agent | C | | 0.3 | | | | | | |

| | | | |
|---|---|---|---|
| plasticizer | 20 | 20 | 10 |

crosslinking agent A: toluene diisocyanate-based crosslinking agent (Coronate-L, Nippon Urethane)

crosslinking agent B: epoxy-based crosslinking agent (Tetrad-X, Mitsubishi Chemical)

crosslinking agent C: diisopropoxyaluminum monostearyl acetoacetate (Hanin Finechem)

plasticizer: di(2-ethylhexyl) phthalate (DEHP, Aekyung Chemical)

### Experimental Example 1: Measurement of Modulus

A storage elasticity modulus of each adhesive sheet of Examples and Comparative Examples. was measured.

For each adhesive sheet, the storage modulus at −20° C. was measured using a viscoelasticity measuring device (MCR-301, Anton Paar). The adhesive sheet was cut to a length of 30 mm×a width of 30 mm, the release film attached to one side of the cut adhesive sheet was removed, and then the adhesive sheet was bonded to a glass substrate. Subsequently, while bonded to a measuring tip, the storage modulus was measured in a temperature range of −20° C. to 100° C. under conditions of a frequency of 1.0 Hz, a deformation of 1% and a heating rate of 5° C./min. The measurement value at −20° C. was obtained, and the measurement results are listed in Tables 4 and 5 below.

### Experimental Example 2: Measurement of Adhesion Force

Each adhesive sheet of Examples and Comparative Examples was cut to a size of 25 mm×100 mm. An adhesion force at 25° C. was measured by leaving the prepared sample under conditions of 25° C. and 50% RH for 24 hours, and then peeling off using a universal tensile testing machine (UTM, instron) at a peeling rate of 300 mm/min and a peeling angle of 180°. An adhesion force at 65° C. was measured by leaving the sample at 65° C. for 3 hours, and then peeling off using a universal tensile testing machine (UTM, instron) at a peeling speed of 300 mm/min and a peeling angle of 180°. The measurement results are listed in Tables 4 and 5 below.

### Experimental Example 3: Evaluation of Foldability

The release film on one side of the adhesive sheet of each of Examples and Comparative Examples was peeled off, the adhesive sheet was bonded to a 50 μm PET film, and then cut to a size of 20 mm×100 mm to form a sample.

The sample was fixed to a flexibility evaluation device (COVOTECH, CFT-720C) for a folding evaluation, and folded to a radius of curvature of 2 mm. The folding evaluation was performed under conditions of −30° C., 60° C., and 60° C. at 90% RH, with 25 folds per minute and a hold of 0.2 seconds after each fold. In the folding evaluation, one folding was defined as one cycle. While performing 50,000 cycles, generation of streak at a folding site, or generation of breakage, lifting or peeling of the adhesive film was considered a defect. A generation time of the defect was identified, and the foldability was evaluated according to the criteria below. The evaluation results are listed in Tables 4 and 5 below.

⊚: No defects occurred after 50,000 or more folding cycles

o: Defects occurred within a range of 20,000 to 50,000 folding cycles

x: Defects occurred at folding cycles less than 20,000 cycles.

TABLE 4

| | | modulus | adhesive force | | foldability | | |
|---|---|---|---|---|---|---|---|
| | | −20° C. | 25° C. | 65° C./ | | | 60° C., |
| | | (kPa) | (N/25 mm) | 25° C. | −30° C. | 60° C. | RH 90% |
| Example | 1 | 80 | 24.3 | 1.03 | ◯ | ⊚ | ◯ |
| | 2 | 69 | 25.1 | 0.88 | ◯ | ⊚ | ◯ |
| | 3 | 65 | 23.7 | 1.09 | ⊚ | ◯ | ◯ |
| | 4 | 70 | 25.8 | 1.01 | ◯ | ◯ | ◯ |
| | 5 | 63 | 26.4 | 1.06 | ◯ | ⊚ | ◯ |
| | 6 | 68 | 24.7 | 0.94 | ◯ | ◯ | ◯ |
| | 7 | 75 | 25.3 | 1.05 | ◯ | ⊚ | ◯ |
| | 8 | 72 | 22.3 | 0.76 | ◯ | ◯ | ◯ |
| | 9 | 78 | 24.1 | 1.06 | ◯ | ⊚ | ◯ |
| | 10 | 74 | 23.1 | 1.11 | ◯ | ⊚ | ◯ |
| | 11 | 62 | 25.1 | 0.87 | ⊚ | ◯ | ◯ |
| | 12 | 71 | 21.5 | 0.97 | ◯ | ◯ | ◯ |
| | 13 | 85 | 26.7 | 1.12 | ◯ | ◯ | ◯ |
| | 14 | 70 | 24.6 | 1.07 | ◯ | ⊚ | ◯ |

TABLE 5

| | | | adhesive force | | foldability | | |
|---|---|---|---|---|---|---|---|
| | | modulus | 25° C. | | | | 60° C., |
| | | −20° C. | (N/25 | 65° C./ | | | RH |
| | | (kPa) | mm) | 25° C. | −30° C. | 60° C. | 90% |
| Comparative | 1 | 134 | 13.4 | 0.5 | X | ◯ | X |
| Example | 2 | 156 | 10.5 | 0.32 | X | X | X |
| | 3 | 129 | 11.2 | 0.3 | X | ◯ | X |
| | 4 | 102 | 9.4 | 0.27 | ◯ | X | X |
| | 5 | 118 | 15.4 | 0.5 | X | X | X |
| | 6 | 107 | 11.6 | 0.41 | X | X | X |
| | 7 | 121 | 12.1 | 0.48 | X | X | X |
| | 8 | 126 | 22.6 | 0.86 | X | ◯ | ◯ |

Referring to Table 4 above, the adhesive sheets of Examples provided a low 5 storage modulus at −20° C., an adhesion force to glass at 25° C. of 16 N/25 mm or greater, and the ratio of an adhesion force at 65° C. to an adhesion force at 25° C. of greater than 0.5, and less than or equal to 1.50. Further, foldability of the adhesive sheets was improved in a low-temperature environment of −30° C. and a high-temperature and/or high-humidity environment of 60° C. and 60° C. RH 90%.

Referring to Table 5 above, in the adhesive sheets of Comparative Examples, the ratio of an adhesion force at 65° C. to an adhesion force at 25° C. was 0.5 or less, and the storage modulus at −20° C. exceeded 100 kPa. Accordingly, the adhesive sheets of Comparative Examples provided degraded low-temperature or high-temperature foldability compared to those from Examples.

The adhesive sheets of Comparative Examples 1 to 3, and 5 included an acrylic copolymer devoid of a repeating unit derived from the (meth)acrylate monomer including an alkyl group having 8 to 12 carbon atoms and/or a repeating unit derived from the (meth)acrylate monomer including an alkyl group having 20 to 30 carbon atoms. Accordingly, low-temperature folding properties, and high-temperature and high-humidity folding properties were degraded. Particularly, the adhesive sheet of Comparative Example 2 did not contain a plasticizer to provide further degraded high-temperature folding properties.

The adhesive sheet of Comparative Example 4 included an acrylic copolymer devoid of a repeating unit derived from a hydroxyl group-containing (meth)acrylate monomer to provide degraded adhesion effect.

The adhesive sheets of Comparative Examples 6 and 8 included an acrylic copolymer failing to satisfy Formula 1 to provide degraded adhesion effects.

The adhesive sheet of Comparative Example 7 included a repeating unit derived from a (meth)acrylate monomer including an alkyl group having 18 carbon atoms instead of the repeating unit derived from a (meth)acrylate monomer including an alkyl group having 20 to 30 carbon atoms, and provided degraded effects of low-temperature modulus.

The above descriptions are merely examples of applying the present inventive concepts, and other elements may be further included without departing from the scope of the present invention.

What is claimed is:

1. An adhesive composition comprising:
a (meth)acrylate copolymer comprising:
a repeating unit derived from a (meth)acrylate monomer including an alkyl group having 8 to 12 carbon atoms;
a repeating unit derived from a (meth)acrylate monomer including an alkyl group having 20 to 30 carbon atoms; and
a repeating unit derived from a hydroxyl group-containing (meth)acrylate monomer,
wherein the (meth)acrylate copolymer satisfies Formula 1:
$$0.3 \leq B / A \leq 4 \qquad [ Formula 1 ]$$
wherein, in Formula 1, A is a content (wt %) of the repeating unit derived from the hydroxyl group-containing (meth)acrylate monomer based on a total weight of the (meth)acrylate copolymer, and
B is a content (wt %) of the repeating unit derived from the (meth)acrylate monomer including an alkyl group having 20 to 30 carbon atoms based on the total weight of the (meth)acrylate copolymer.

2. The adhesive composition of claim 1, wherein the (meth)acrylate copolymer satisfies Formula 2:
$$0.5 \leq B / A \leq 1.2 . \qquad [ Formula 2 ] .$$

3. The adhesive composition of claim 1, wherein A in Formula 1 is in a range from 10 to 60.

4. The adhesive composition of claim 1, wherein B in Formula 1 is in a range from 10 to 45.

5. The adhesive composition of claim 1, wherein the (meth)acrylate monomer including an alkyl group having 20 to 30 carbon atoms includes a branched-chain alkyl group having 20 to 30 carbon atoms.

6. The adhesive composition of claim 1, wherein the content of the repeating unit derived from the (meth)acrylate monomer including an alkyl group having 8 to 12 carbon atoms is in a range from 10 wt % to 80 wt % based on the total weight of the (meth)acrylate copolymer.

7. The adhesive composition of claim 1, wherein the (meth)acrylate copolymer further comprises a repeating unit derived from a carboxyl group-containing (meth)acrylate monomer.

8. The adhesive composition of claim 7, wherein the content of the repeating unit derived from the carboxyl group-containing (meth)acrylate monomer is greater than 0, and less than or equal to 5 wt % based on the total weight of the (meth)acrylate copolymer.

9. The adhesive composition of claim 7, wherein the (meth)acrylate copolymer satisfies Formula 3:
$$0 < C / A \leq 0.1 . \qquad [ Formula 3 ]$$
wherein, in Formula 3, A is the content (wt %) of the repeating unit derived from the hydroxyl group-containing (meth)acrylate monomer based on the total weight of the (meth)acrylate copolymer, and
C is a content (wt %) of the repeating unit derived from the carboxyl group-containing (meth)acrylate monomer based on the total weight of the (meth)acrylate copolymer.

10. The adhesive composition of claim 1, further comprising a crosslinking agent, wherein a content of the crosslinking agent is greater than 0, and less than or equal to 3 parts by weight based on 100 parts by weight of the (meth)acrylate copolymer.

11. An adhesive sheet comprising an adhesive layer formed from the adhesive composition according to claim 1.

12. An image display device comprising:
a display panel; and
the adhesive sheet of claim 11 disposed on the display panel.

13. An adhesive sheet comprising:
an adhesive layer comprising a (meth)acrylate copolymer,
wherein an adhesive force of the adhesive layer at 25° C. is 16 N/25 mm or more, and a storage modulus of the adhesive layer at −20° C. is in a range from 50 kPa to 120 kPa,
wherein the adhesive force is measured by laminating the adhesive layer to a glass substrate, maintaining for 24 hours under conditions of 25° C. and 50% RH, and then peeling the adhesive layer at a peeling speed of 300 mm/min and a peeling angle of 180°.

14. The adhesive sheet of claim 13, wherein the (meth)acrylate copolymer comprises:
a repeating unit derived from a (meth)acrylate monomer including an alkyl group having 8 to 12 carbon atoms;
a repeating unit derived from a (meth)acrylate monomer including an alkyl group having 20 to 30 carbon atoms; and
a repeating unit derived from a hydroxyl group-containing (meth)acrylate monomer.

15. An adhesive sheet comprising:
an adhesive layer comprising a (meth)acrylate-based copolymer,
wherein a ratio of an adhesive force at 65° C. to an adhesive force at 25° C. of the adhesive layer is greater than 0.5, and less than or equal to 1.5,
wherein the adhesive force at 25° C. is measured by laminating the adhesive layer to a glass substrate, maintaining under conditions of 25° C. and 50% RH for 24 hours, and then peeling the adhesive layer at a peeling speed of 300 mm/min and a peeling angle of 180°, and
the adhesive force at 65° C. is measured by laminating the adhesive layer to a glass substrate, maintaining under conditions of 65° C. for 3 hours, and then peeling the adhesive layer at a peeling speed of 300 mm/min and a peeling angle of 180°.

16. The adhesive sheet according to claim 15, wherein the (meth)acrylate copolymer comprises:
a repeating unit derived from a (meth)acrylate monomer including an alkyl group having 8 to 12 carbon atoms;
a repeating unit derived from a (meth)acrylate monomer including an alkyl group having 20 to 30 carbon atoms; and
a repeating unit derived from a hydroxyl group-containing (meth)acrylate monomer.
